(19) United States
(12) Patent Application Publication
(10) Pub. No.: US 2003/0027060 A1
(43) Pub. Date: Feb. 6, 2003

(54) Photoresist and process for structuring such a photoresist

(76) Inventor: Kay Lederer, Dresden (DE)

Correspondence Address: LERNER AND GREENBERG, P.A., Post Office Box 2480, Hollywood, FL, 33022-2480, US

(21) Appl. No.: 10/213,411

(22) Filed: Aug. 5, 2002

(30) Foreign Application Priority Data
Aug. 3, 2001 (DE) 101 38 105.0

(51) Int. Cl. G03F 9/00

(52) U.S. Cl. 430/5; 430/313; 430/317; 430/950; 430/954

(57) ABSTRACT

A negative photoresist for transferring a photomask to a semiconductor wafer includes a passivated component that is activated by an exposure radiation, the activated component being configured to interact with the uppermost layer of the semiconductor wafer at the interface, the interaction ensuring increased adhesion between the negative photoresist and the substrate. Alternatively, a positive photoresist for transferring a photomask to a semiconductor wafer includes a component that is passivated by an exposure radiation, the activated component being configured to interact with the uppermost layer of the semiconductor wafer at the interface, the interaction ensuring increased adhesion between the positive photoresist and the substrate.

### BACKGROUND OF THE INVENTION

Field of the Invention

The invention relates to a process for forming a structured photoresist layer on a semiconductor substrate, and a photoresist for use in such a process.

Integrated-circuits on semiconductor substrates are generally produced with the aid of a planar technique. In the planar technique, local processing of semiconductor wafers is carried out by using lithographic processes. In the photolithographic processes, a thin radiation-sensitive film, a so-called photoresist layer, is first applied to the semiconductor wafer. The photoresist layer is exposed to light through a suitable mask that contains the structure to be formed in the semiconductor substrate. Alternatively, however, X-rays may also be used for forming the structures on the photoresist layer. It is also possible to form the desired structures directly on the photoresist with the aid of an electron beam. After the formation of the structures on the photoresist layer, the resist is developed and then cured. The structure thus produced in the photoresist layer is then transferred with the aid of special etching processes into the semiconductor layer underneath. However, the photoresist layer can, itself, serve as a local mask for the semiconductor layer, for example, for ion implantation.

Photolithography can be divided into a positive and a negative resist technique. In the positive resist technique, the photoresist becomes detached in the exposed parts during development of the resist, whereas the unexposed parts remain masked. In the negative resist technique, the situation is exactly the opposite. The exposed parts remain masked after development of the resist, whereas the unexposed parts dissolve during development.

The increasing miniaturization of the integrated circuits makes it necessary to form increasingly small structure widths in the photoresist layer using the lithographic technique. The use of the structured photoresist layer as an etching mask for structuring the semiconductor layer underneath simultaneously requires a predetermined minimum layer thickness to ensure that the photoresist layer withstands the etching. The result of this is that, with increasingly small component widths, the aspect ratio of the photoresist structures, i.e., the ratio of width to height of the individual structures, is becoming increasingly unfavorable. This increases the danger of the resist structures collapsing in the subsequent process step, which may then lead to incorrect structures when the resist structures are transferred to the semiconductor layer and, hence, to incorrect integrated circuits.

Good resist adhesion on the semiconductor surface is, therefore, necessary for preventing a collapse of the resist structures. To improve the adhesion of the photoresist on the semiconductor surface, surface wetting with a so-called primer, usually hexamethyldisilazane (HMDS) in the case of silicon wafers, is generally carried out before application of the resist. The wetting of the silicon wafer with HMDS produces an organic surface that gives a large contact angle with the customarily likewise organic photoresist layer and, hence, ensures a large contact surface with the photoresist. As an alternative to the use of HMDS as a primer, an organic antireflection layer is also used between the photoresist layer and the semiconductor substrate, which antireflection layer, similarly to the HMDS layer, produces an organic surface on the silicon wafer and additionally ensures a reduction in reflection on exposure of the photoresist layer to light. In spite of the use of such primers, however, there is still the danger of a collapse of the photoresist structures, in particular, in the case of structure widths in the sub-μm range.

### SUMMARY OF THE INVENTION

It is accordingly an object of the invention to provide a photoresist and process for structuring such a photoresist that overcomes the hereinafore-mentioned disadvantages of the heretofore-known devices and methods of this general type and that ensures improved resist adhesion on the semiconductor surface.

With the foregoing and other objects in view, there is provided, in accordance with the invention, a method of forming a structured photoresist layer on a semiconductor wafer, including the steps of applying a negative photoresist layer over substantially all of an uppermost layer of the semiconductor wafer, the negative photoresist having, at least in a region of an interface with the uppermost layer, a passivated component activatable by exposure radiation in an exposed portion to interact, at the interface, with the uppermost layer, the interaction ensuring increased adhesion between the negative photoresist layer and the uppermost layer, exposing portions of the negative photoresist layer with the exposure radiation to form a structure on the negative photoresist layer, and developing the negative photoresist layer to remove the negative photoresist layer in unexposed portions of the negative photoresist layer. Alternatively, the negative photoresist layer can be applied over at least a portion of the uppermost layer of the semiconductor wafer.

With the objects of the invention in view, there is also provided a method of forming a structured photoresist layer on a semiconductor wafer, including the steps of applying a positive photoresist layer over substantially all of an uppermost layer of the semiconductor wafer, the positive photoresist having an activated component at least in a region of an interface with the uppermost layer to interact, at the interface, with the uppermost layer, the interaction ensuring increased adhesion between the positive photoresist layer and the uppermost layer, exposing portions of the positive photoresist layer with exposure radiation to form a structure on the positive photoresist layer and to passivate the activated component in the exposed portions, and developing the positive photoresist layer to remove the positive photoresist layer in unexposed portions of the positive photoresist layer. Alternatively, the positive photoresist layer can be applied over at least a portion of the uppermost layer of the semiconductor wafer.

According to the invention, a negative photoresist for transferring a photomask to an uppermost layer of a semiconductor wafer contains a passivating component that is activated by an exposure radiation, the activated component being configured to interact at the interface with the uppermost layer of the semiconductor wafer, and the interaction ensuring stronger adhesion between the negative photoresist and the uppermost layer of the semiconductor wafer. Alternatively, according to the invention, a positive photoresist for transferring a photomask to an uppermost layer of a semiconductor wafer has a component that is passivated by an exposure radiation, the activated component being configured to interact at the interface with the uppermost layer of the semiconductor wafer, and the interaction ensuring stronger adhesion between the positive photoresist and the uppermost layer of the semiconductor wafer.

Such a positive or negative photoresist according to the invention ensures substantially improved adhesion of the resist structures produced in the lithography technique to the semiconductor substrate. The additional component provided in the photoresist, preferably, forms a chemical bond, for example, crosslinks, with the surface of the layer on the semiconductor wafer and, thus, ensures a substantial increase in the adhesion of the photoresist to the surface.

Because the adhesion-promoting component in the negative photoresist is transformed from a passive state, in which it does not as yet interact with the substrate material, into an activated state, in which the interaction is then established, only by the exposure radiation, it is ensured that, in the negative photoresist, stronger adhesion is produced only in the exposed parts so that the unexposed parts can still be removed in a simple manner by the developing process. In addition to improved adhesion of the negative photoresist structure, the process ensures error-free structuring of the photoresist during the development of the resist. In the case of the positive photoresist according to the invention, the adhesion-promoting component is distinguished by the fact that it is transformed by the exposure process from an activated state, in which it interacts with the resist substrate, into a passivated state, in which the improved adhesion effect is eliminated. This makes it possible to remove the exposed parts of the positive photoresist during the development step in a simple manner, at the same time the activated components in the unexposed parts ensuring stronger adhesion of the positive photoresist structures and, thus, reliably preventing collapse of the resist lines.

In accordance with another mode of the invention, a chemical reaction of the activated component is initiated after the exposure process, preferably, by a thermal treatment of the semiconductor wafer with the still undeveloped photoresist layer, to initiate a chemical bonding process between the activated component of the photoresist and the substrate. As a result of such a configuration of the lithography technique, simplified handling of the photoresist is ensured. By providing an additional reaction step, it is possible to choose for the photoresist a component that, on one hand, can be optimally transformed by the exposure radiation into an active state and then, by a defined chemical reaction, ensures improved adhesion of the photoresist in the region of the active components.

In accordance with a further mode of the invention, the semiconductor wafer has, as a substrate under the resist layer, an additional layer that likewise contains reactive components that interact with the activated components of the photoresist. This makes it possible to achieve further improvement in the chemical bond formation between the photoresist layer and the substrate and, hence, improved adhesion.

With the objects of the invention in view, there is also provided a negative photoresist for transferring a photomask to an interface of an uppermost layer of a semiconductor substrate, including a passivated component activatable by an exposure radiation, the passivated component interacting, at the interface, with the uppermost layer, to ensure increased adhesion between the negative photoresist and the semiconductor substrate.

With the objects of the invention in view, there is also provided a photomask transfer device, including a semiconductor substrate having an uppermost layer, a negative photoresist for transferring a photomask to an interface of the uppermost layer, the negative photoresist having a passivated component activatable by an exposure radiation and being disposed at the uppermost layer at an interface, and the passivated component interacting, at the interface, with the uppermost layer, to ensure increased adhesion between the negative photoresist and the semiconductor substrate.

With the objects of the invention in view, there is also provided a positive photoresist for transferring a photomask to an interface of an uppermost layer of a semiconductor substrate, including an activated component passivated by an exposure radiation, the activated component interacting, at the interface, with the uppermost layer, to ensure increased adhesion between the positive photoresist and the semiconductor substrate.

With the objects of the invention in view, there is also provided a photomask transfer device, including a semiconductor substrate having an uppermost layer, a positive photoresist for transferring a photomask to an interface of the uppermost layer, the positive photoresist having an activated component passivated by an exposure radiation, and the activated component interacting, at the interface, with the uppermost layer, to ensure increased adhesion between the positive photoresist and the semiconductor substrate.

Other features that are considered as characteristic for the invention are set forth in the appended claims.

Although the invention is illustrated and described herein as embodied in a photoresist and process for structuring such a photoresist, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIGS. 1A to 1E are diagrammatic, fragmentary, cross-sectional views of various steps in a lithography process using a negative resist according to the invention; and

FIGS. 2A to 2E are diagrammatic, fragmentary, cross-sectional views of various steps in a lithography process using a positive resist according to the invention.

### DESCRIPTION OF THE PREFERRED EMBODIMENTS

In the planar technique usually used for the formation of a highly integrated circuit, the local processing of the semiconductor wafers is carried out with the aid of lithographic processes. The structures are first produced by a photomask in a thin, radiation-sensitive film, usually an organic photoresist layer, on the semiconductor wafer and then transferred in special etching processes into the semiconductor layer underneath. In some cases, for example, in the case of ion implantation, the photoresist itself may also serve as a local mask.

The photolithography technique is divided into a positive and a negative resist technique. In the positive resist technique, the photoresist becomes detached in the exposed parts during the development, whereas the unexposed parts remain masked. In the negative resist technique, the exposed parts are masked after development, whereas the unexposed resist parts are dissolved during the development. The photoresists usually are of a solid matrix component and a photosensitive constituent. Generally used as photoresists are polymers, the negative photoresist being configured so that the matrix material with the photosensitive constituent can be dissolved as unexposed mixture by a developer liquid. On the other hand, the positive photoresists are not attacked by the developer solution in the unexposed state.

Good adhesion of the resist on the semiconductor wafer is necessary for ensuring error-free masking or structuring of the semiconductor wafers. This is all the more true because, due to the increasing miniaturization of the highly integrated circuits, the semiconductor structures are becoming, increasingly narrow.

Before the application of the resist, the surface of the semiconductor wafer is usually wet with a so-called primer, preferably hexamethyldisilazane (HMDS) in the case of silicon. Such a primer ensures a passivation of the semiconductor surface and increases the contact angle and, hence, the retention of the resist deposited on the primer. An organic antireflection layer is also often used as a primer, which antireflection layer additionally prevents the exposure radiation from being reflected by the semiconductor surface and, hence, modifying the exposure radiation due to interference effects.

According to the invention, to achieve improved adhesion between the structured photoresist and the substrate underneath and, thus, reliably to prevent a collapse of the resist lines due to mechanical and/or chemical loads after the development of the resist, a component that forms a chemical bond with the substrate in the parts defined by the photomask is provided in the photoresist. In the case of positive photoresists, the reactive component is configured so that it is passivated in the initial state and is activated only by the exposure radiation to interact with the substrate at the interface. The configuration ensure that chemical bond formation, for example, crosslinking between the positive photoresist and the substrate, and, hence, improved adhesion also occurs only where the positive photoresist is to remain. The other unexposed parts can then be removed in a simple manner by the development process, as in the case of conventional positive photoresists.

Conversely, in the case of negative photoresists, the reactive component that ensures additional adhesion on the substrate is configured so that it is already activated in the initial state and is passivated again only by the exposure radiation. Such a configuration reliably ensures that improved adhesion to the substrate is provided by the reactive component only in the exposed parts of the negative photoresist that are to remain after development.

The reactive component of the photoresist is preferably configured so that it has an adhesion-promoting effect or liberates adhesion-promoting components that chemically combine, preferably, crosslink, with the substrate material, only as a result of an additional activation process, preferably, a thermal treatment of the resist. It is also preferable if the adhesion promoter usually disposed under the photoresist likewise contains reactive components that interact with the activated components in the photoresist. As a result, additional improved adhesion is achieved.

Active compounds can form as a result of exposure to light and/or heat supply and are capable of converting a so-called precursor into a reactive compound. Acids form photolytically, for example, as a result of the exposure of the following compounds to light: onium acid, halogenated compounds, sulfonic acid, sulfonic esters, diazonium salts, perhalomethyltriazines, diaryliodonium salts, triarylsulfonium salts, ortho-nitrobenzyl esters, phloroglucinolsulfonates, bromobisphenol A, hydroxamic acid, diazosulfonates, etc. Thermolytically producible compounds that are capable of forming a chemical bond are either compounds in which rearrangements, bond cleavage, or other types of chemical activation take place as a result of the supply of heat, or compounds that contain functional groups that are protected by a chemical protective group (benzyl, tertiary carbonyl, carbonyl, acetal, epoxy, etc.), which, in turn, can be cleaved by heat supply.

A precursor is sensitive to the active compound and/or energy supply through heat or light by virtue of the fact that it liberates the reactive compound as a result of reaction with the active compound and/or as a result of the supply of heat or light. The precursor itself is not-reactive. Examples of the reaction of an active compound with a precursor arc the removal of a chemical protective group, a molecular rearrangement, or any type of chemical bond cleavage.

Reactive compounds are monomers and/or polymers that have functional groups that are capable of undergoing chemical reactions either with themselves or with other reactive compounds. Reactive compounds may be functionalized derivatives of the parent polymer and/or polymers or monomers that are usually used in semiconductor photoresist technology. Examples of polymers that are usually used in semiconductor photoresist technology are: novolak, poly(methyl methacrylate), poly(isopropenyl ketone), poly(p-hydroxystyrene), poly(anthryl methacrylate), poly(vinyl methyl ether-co-maleic anhydride), poly(styrene-co-maleic anhydride), fluorinated and silicon-containing polymers, etc. Functional groups are molecular units that are capable of forming a chemical bond with other functional groups as a result of the supply of energy, preferably, thermal energy. Examples of functional groups are: carbonyl, amine, imine, amide, imide, hydroxyl, acyl, amyl, acetal, hemiacetal, ethers, esters and phenolic groups, unsaturated groups (aryl, alkene, alkyne, aryne), silanol groups, etc. Crosslinking, cyclization or σ-bond formation are examples of chemical reactions of reactive compounds that lead to chemical amplification of photoresist lines in the context of the present invention.

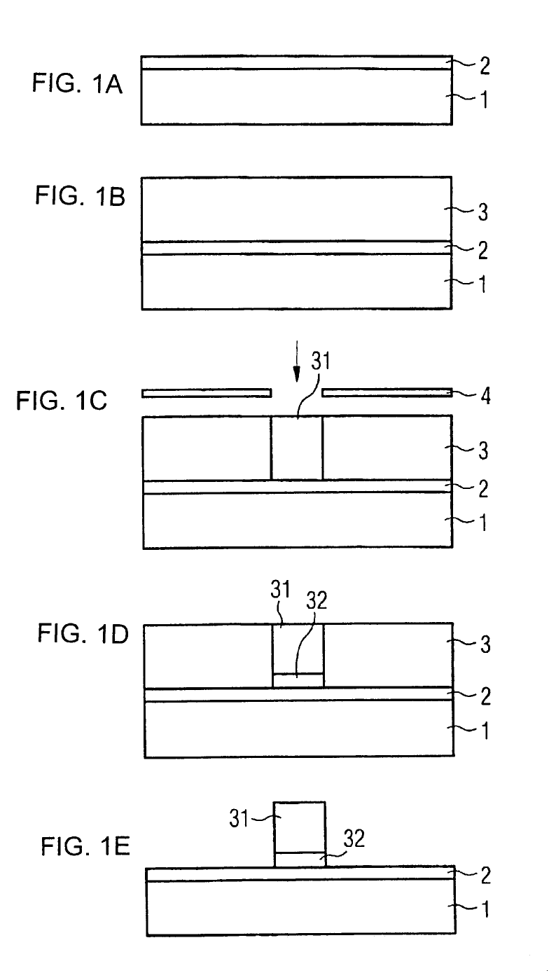

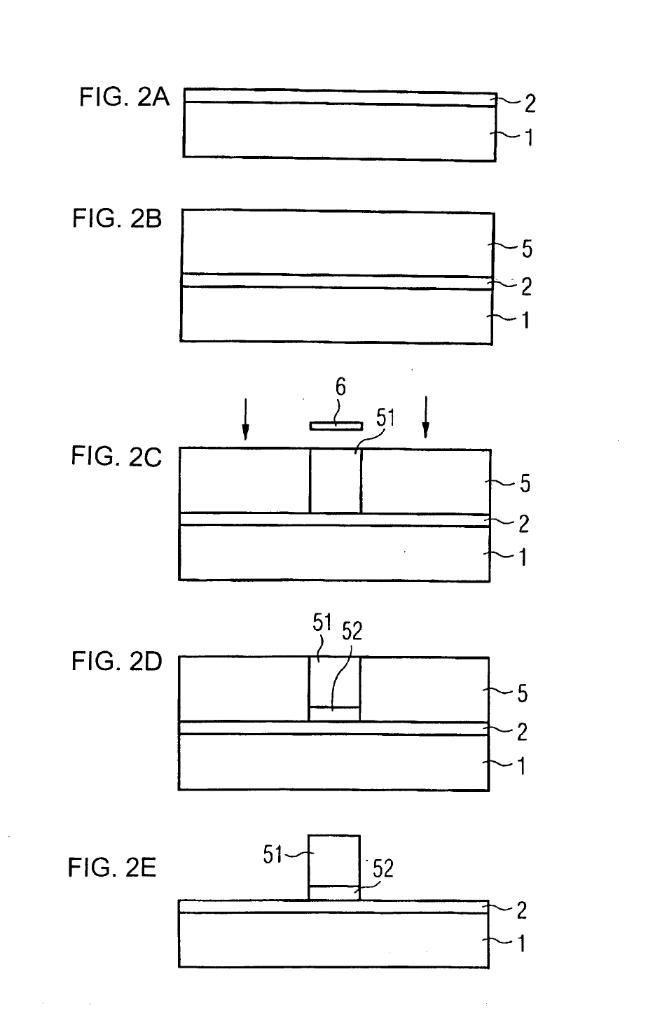

Referring now to the figures of the drawings in detail and first, particularly to FIG. 1 thereof, there is shown a lithography process with a negative resist according to the invention, and FIG. 2 shows a corresponding lithography process for a positive resist. In a first step, as shown in FIG. 1A and FIG. 2A, a primer layer 2 is applied to the semiconductor substrate 1. In the case of a silicon wafer, the application is generally effected by exposing the wafers to the vapor of an HMDS liquid in vacuo or at atmospheric pressure in a nitrogen environment so that wetting of the semiconductor surface results. A radiation-sensitive photoresist 3 is then applied by spin coating. This is shown for a negative photoresist 3 in FIG. 1B and for a positive photoresist 5 in FIG. 2B. An exposure step for producing the desired resist structure in the radiation-sensitive photoresist is then carried out.

In the case of the negative photoresist, a photomask 4 in which the parts of the negative photoresist layer in which the resist structures are to be produced are transparent is used for such a purpose, as shown in FIG. 1C. The radiation ensures that the negative photoresist is insoluble with respect to the developer liquid in the exposed parts. At the same time, the passivated adhesion component contained in the photoresist is activated. By a subsequent thermal step, which is shown in FIG. 1D, a chemical reaction is initiated with the activated component in the exposed parts of the photoresist layer 3, in which reaction there is an interaction between the activated component and the substrate material, in the present case, the primer layer 2. This bonding region 32 ensures improved adhesion of the resist in these parts to the substrate. The unexposed parts of the negative resist layer 3 are then removed by developing, as shown in FIG. 1E, to form a desired resist pattern 31.

In the case of the positive resist process, as shown in FIG. 2C, those parts of the positive photoresist layer 5 that are to be subsequently removed in the developer liquid are exposed by a photomask 6. The exposure process initiates a chemical reaction in the positive resist, which makes the positive resist, which is actually insoluble in the developer liquid, soluble. At the same time, an activated component that can interact with the substrate is passivated by the exposure radiation. After the exposure process, a chemical reaction is initiated as shown in FIG. 2D, preferably by a thermal step, which bonds the remaining activated components in the positive resist to the primer layer underneath and, thus, ensures improved adhesion of the positive resist in the part 52. The exposed parts of the positive resist are then removed with the aid of developer liquid, as shown in FIG. 2E, so that the desired resist structure 51 forms.

The features of the invention that are disclosed in the above description, the drawings, and the claims may be important both individually and in any desired combination for realizing the invention in its various embodiments.

I claim:

1. A method of forming a structured photoresist layer on a semiconductor wafer, which comprises:
applying a negative photoresist layer over substantially all of an uppermost layer of the semiconductor wafer, the negative photoresist having, at least in a region of an interface with the uppermost layer, a passivated component activatable by exposure radiation in an exposed portion to interact, at the interface, with the uppermost layer, the interaction ensuring increased adhesion between the negative photoresist layer and the uppermost layer;
exposing portions of the negative photoresist layer with the exposure radiation to form a structure on the negative photoresist layer; and
developing the negative photoresist layer to remove the negative photoresist layer in unexposed portions of the negative photoresist layer.

2. The process according to claim 1, which further comprises initiating a chemical reaction of the component causing the interaction with the uppermost layer at the interface after the exposure process.

3. The process according to claim 1, wherein the semiconductor wafer has, as the uppermost layer, a layer having a reactive component interacting with the passivated component in the photoresist layer.

4. A method of forming a structured photoresist layer on a semiconductor wafer, which comprises:
applying a negative photoresist layer over at least a portion of an uppermost layer of the semiconductor wafer, the negative photoresist having, at least in a region of an interface with the uppermost layer, a passivated component activatable by exposure radiation in an exposed portion to interact, at the interface, with the uppermost layer, the interaction ensuring increased adhesion between the negative photoresist layer and the uppermost layer;
exposing portions of the negative photoresist layer with the exposure radiation to form a structure on the negative photoresist layer; and
developing the negative photoresist layer to remove the negative photoresist layer in unexposed portions of the negative photoresist layer.

5. The process according to claim 4, which further comprises initiating a chemical reaction of the component causing the interaction with the uppermost layer at the interface after the exposure process.

6. The process according to claim 4, wherein the semiconductor wafer has, as the uppermost layer, a layer having a reactive component interacting with the passivated component in the photoresist layer.

7. A method of forming a structured photoresist layer on a semiconductor wafer, which comprises:
applying a positive photoresist layer over substantially all of an uppermost layer of the semiconductor wafer, the positive photoresist having an activated component at least in a region of an interface with the uppermost layer to interact, at the interface, with the uppermost layer, the interaction ensuring increased adhesion between the positive photoresist layer and the uppermost layer;
exposing portions of the positive photoresist layer with exposure radiation to form a structure on the positive photoresist layer and to passivate the activated component in the exposed portions; and
developing the positive photoresist layer to remove the positive photoresist layer in unexposed portions of the positive photoresist layer.

8. The process according to claim 7, which further comprises initiating a chemical reaction of the component causing the interaction with the uppermost layer at the interface after the exposure process.

9. The process according to claim 7, wherein the semiconductor wafer has, as the uppermost layer, a layer having a reactive component interacting with the activated component in the photoresist layer.

10. A method of forming a structured photoresist layer on a semiconductor wafer, which comprises:
applying a positive photoresist layer over at least a portion of an uppermost layer of the semiconductor wafer, the positive photoresist having an activated component at least in a region of an interface with the uppermost layer to interact, at the interface, with the uppermost layer, the interaction ensuring increased adhesion between the positive photoresist layer and the uppermost layer;
exposing portions of the positive photoresist layer with exposure radiation to form a structure on the positive photoresist layer and to passivate the activated component in the exposed portions; and
developing the positive photoresist layer to remove the positive photoresist layer in unexposed portions of the positive photoresist layer.

11. The process according to claim 10, which further comprises initiating a chemical reaction of the component causing the interaction with the uppermost layer at the interface after the exposure process.

12. The process according to claim 10, wherein the semiconductor wafer has, as the uppermost layer, a layer having a reactive component interacting with the activated component in the photoresist layer.

13. A negative photoresist for transferring a photomask to an interface of an uppermost layer of a semiconductor substrate, comprising:
a passivated component activatable by an exposure radiation, said passivated component interacting, at the interface, with the uppermost layer, to ensure increased adhesion between said negative photoresist and the semiconductor substrate.

14. A photoresist for transferring a photomask to an interface of an uppermost layer of a semiconductor substrate, comprising:
a negative photoresist having a passivated component activatable by an exposure radiation, said passivated component interacting, at the interface, with the uppermost layer, to ensure increased adhesion between said negative photoresist and the semiconductor substrate.

15. A photomask transfer device, comprising:
a semiconductor substrate having an uppermost layer;
a negative photoresist for transferring a photomask to an interface of said uppermost layer, said negative photoresist:
having a passivated component activatable by an exposure radiation; and
being disposed at said uppermost layer at an interface; and
said passivated component interacting, at said interface, with said uppermost layer, to ensure increased adhesion between said negative photoresist and said semiconductor substrate.

16. In a semiconductor substrate having an uppermost layer, a photoresist for transferring a photomask to an interface of the uppermost layer, comprising:
a negative photoresist having a passivated component activatable by an exposure radiation, said passivated component interacting, at the interface, with the uppermost layer, to ensure increased adhesion between said negative photoresist and the semiconductor substrate.

17. A positive photoresist for transferring a photomask to an interface of an uppermost layer of a semiconductor substrate, comprising:
an activated component passivated by an exposure radiation, said activated component interacting, at the interface, with the uppermost layer, to ensure increased adhesion between said positive photoresist and the semiconductor substrate.

18. A photoresist for transferring a photomask to an interface of an uppermost layer of a semiconductor substrate, comprising:
a positive photoresist having an activated component passivated by an exposure radiation, said activated component interacting, at the interface, with the uppermost layer, to ensure increased adhesion between said positive photoresist and the semiconductor substrate.

19. A photomask transfer device, comprising:
a semiconductor substrate having an uppermost layer;
a positive photoresist for transferring a photomask to an interface of said uppermost layer, said positive photoresist having an activated component passivated by an exposure radiation; and
said activated component interacting, at said interface, with said uppermost layer, to ensure increased adhesion between said positive photoresist and said semiconductor substrate.

20. In a semiconductor substrate having an uppermost layer, a photoresist for transferring a photomask to an interface of the uppermost layer, comprising:
a positive photoresist having an activated component passivated by an exposure radiation, said activated component interacting, at the interface, with the uppermost layer, to ensure increased adhesion between said positive photoresist and the semiconductor substrate.
